(19) United States
(12) Patent Application Publication
(10) Pub. No.: US 2015/0037937 A1
(43) Pub. Date: Feb. 5, 2015

(54) SEMICONDUCTOR DEVICES INCLUDING ELECTROMAGNETIC INTERFERENCE SHIELD

(71) Applicant: SAMSUNG ELECTRONICS CO., LTD., Suwon-si (KR)

(72) Inventors: Su-Min PARK, Ansan-si (KR); Jong-Ho LEE, Hwaseong-si (KR)

(73) Assignee: SAMSUNG ELECTRONICS CO., LTD., Suwon-si (KR)

(21) Appl. No.: 14/486,372

(22) Filed: Sep. 15, 2014

Related U.S. Application Data
(62) Division of application No. 13/778,467, filed on Feb. 27, 2013.

(30) Foreign Application Priority Data
Apr. 2, 2012 (KR) 10-2012-0033935

(51) Int. Cl. H01L 21/48; H01L 23/00

(52) U.S. Cl. CPC H01L 21/4817; H01L 24/85; H01L 2924/166
USPC 438/107

(57) ABSTRACT

Provided are a semiconductor device including an EMI shield, a method of manufacturing the same, a semiconductor module including the semiconductor device, and an electronic system including the semiconductor device. The semiconductor device includes a lower semiconductor package, an upper semiconductor package, a package bump, and an EMI shield. The lower semiconductor package includes a lower substrate, a lower semiconductor chip mounted on the lower substrate, and a ground wire separated from the lower semiconductor chip. The upper semiconductor package includes an upper substrate stacked on the lower semiconductor package, and an upper semiconductor chip stacked on the upper substrate. The package bump electrically connects the upper semiconductor package and the lower semiconductor package. The EMI shield covers the upper and lower semiconductor packages and is electrically connected to the ground wire.

### CROSS-REFERENCE TO RELATED APPLICATIONS

This application is a Divisional Application of prior application Ser. No. 13/778,467, filed on Feb. 27, 2013 in the United States Patent and Trademark Office, which claims priority under 35 U.S.C. §119 to Korean Patent Application No. 10-2012-0033935 filed on Apr. 2, 2012, the disclosure of which is hereby incorporated by reference in its entirety.

### BACKGROUND

1. Field

Embodiments of the inventive concept relate to a semiconductor device including an electromagnetic interference (EMI) shield, a method of manufacturing the same, a semiconductor module including the semiconductor device, and an electronic system.

2. Description of the Related Art

EMI that occurs in semiconductor devices due to an induced electromagnetic field is a factor contributing to degradation of the performance of the semiconductor devices.

Accordingly, various structures and methods for shielding EMI that occurs in semiconductor devices are being proposed.

### SUMMARY

Embodiments of the inventive concept provide a semiconductor device including an EMI shield to shield an EMI and a ground unit that grounds the EMI shield.

Embodiments of the inventive concept provide a semiconductor device including a cover as the EMI shield.

Embodiments of the inventive concept provide a semiconductor device including a ground line, which is exposed to a side surface of a lower substrate, as the ground unit.

Embodiments of the inventive concept provide a semiconductor device including a ground wire as the ground unit.

Embodiments of the inventive concept provide a semiconductor device including a ground wire and a ground line (which is exposed to the side surface of the lower substrate) as the ground unit.

Embodiments of the inventive concept provide a semiconductor device including a conductive material disposed between the ground unit and the EMI shield.

Embodiments of the inventive concept provide a method of manufacturing a semiconductor device including an EMI shield and a ground unit.

Embodiments of the inventive concept provide a method of manufacturing a semiconductor device including an EMI shield, a ground unit, and a conductive material disposed therebetween.

Additional features and utilities of the present general inventive concept will be set forth in part in the description which follows and, in part, will be obvious from the description, or may be learned by practice of the general inventive concept.

The foregoing and/or other features and utilities of the present general inventive concept may be achieved by providing a semiconductor device which may include a lower semiconductor package having a lower substrate, a lower semiconductor chip mounted on the lower substrate, and a ground wire formed on the lower substrate, an upper semiconductor package stacked on the lower semiconductor package and having an upper substrate and an upper semiconductor chip which is mounted on the upper substrate, a package bump configured to electrically connect the upper semiconductor package and the lower semiconductor package, and a conductive cover electrically connected to the ground wire and configured to cover the upper semiconductor package and the lower semiconductor package.

The semiconductor device may include a conductive material formed between the stacked upper and lower semiconductor packages and the conductive cover, and configured to electrically connect the ground wire and the conductive cover.

The semiconductor device may include a ground via formed inside the lower substrate and electrically connected to the ground wire, and a ground line electrically connected to the ground via.

The semiconductor device may include a ground wire pad formed at a top of the lower substrate and configured to electrically connect the ground wire and the ground via.

The lower semiconductor package may further include a lower molding material surrounding a side surface of the lower semiconductor chip and a side surface of the package bump, an end portion of the ground wire being exposed to a side surface of the lower molding material.

The foregoing and/or other features and utilities of the present general inventive concept may also be achieved by providing a semiconductor device including a lower semiconductor package having a lower substrate, one or more semiconductor chips mounted on the lower substrate, and a ground unit connected to the lower substrate, an upper semiconductor package having an upper substrate and one or more semiconductor chips mounted on the upper substrate and mounted on the lower semiconductor package, and a cover to accommodate the lower semiconductor package and the upper semiconductor package and electrically connected to the ground unit to provide an EMI shield.

The ground unit may include a wire connected between the cover and the lower substrate of the lower semiconductor package.

The ground unit may include a ground line exposed from a side surface of the lower substrate to be electrically connected to the cover when the cover covers the upper semiconductor package and the lower semiconductor package.

The semiconductor device may further include a conductive material formed between the cover and at least one of the lower semiconductor package and the upper semiconductor package. The conductive material may be electrically connected to the ground unit when the cover covers the upper semiconductor package and the lower semiconductor package.

The foregoing and/or other features and utilities of the present general inventive concept may also be achieved by providing a semiconductor device a module including a module substrate, a terminal formed on the module substrate to be connectable to an external apparatus, and the above descried semiconductor device to be mounted on the module substrate and to be electrically connected to the terminal.

The foregoing and/or other features and utilities of the present general inventive concept may also be achieved by providing an electronic system including a body formed with a power supply and a functional unit, a display unit, and a control unit having the above described semiconductor device to control the power supply, the functional unit, and the display unit.

The foregoing and/or other features and utilities of the present general inventive concept may also be achieved by providing a method of manufacturing a semiconductor device, the method including forming a lower semiconductor package having a lower substrate, one or more semiconductor chips mounted on the lower substrate, and a ground unit connected to the lower substrate, forming an upper semiconductor package having an upper substrate and one or more semiconductor chips mounted on the upper substrate and mounted on the lower semiconductor package, and covering the lower semiconductor package and the upper semiconductor package with a cover and electrically connecting the cover to the ground unit to provide an EMI shield.

The method may include forming a wire as the ground unit to be connected between the cover and the lower substrate of the lower semiconductor package, and connecting the wire to the cover during the covering operation as the EMI shield.

The method may further include forming a ground line as the ground unit to be exposed through a side surface of the lower substrate, and connecting the ground line to the cover during the covering operation as the EMI shield.

The method may further include forming a conductive material to be disposed between the cover and at least one of the lower semiconductor package and the upper semiconductor package, and connecting the ground unit to the conductive material as the EMI shield.

### BRIEF DESCRIPTION OF THE DRAWINGS

The foregoing and other features and utilities of the inventive concepts will be apparent from the more particular description of preferred embodiments of the inventive concepts, as illustrated in the accompanying drawings in which like reference characters refer to the same parts throughout the different views. The drawings are not necessarily to scale, emphasis instead being placed upon illustrating the principles of the inventive concepts. In the drawings:

FIG. 1A is a perspective view schematically illustrating a semiconductor device in accordance with an embodiment of the inventive concept;

FIG. 1B is a cross-sectional view schematically illustrating a semiconductor device in accordance with an embodiment of the inventive concept;

FIGS. 2A and 2B are perspective views illustrating a semiconductor device having a ground wire disposed at a top of a lower substrate thereof in accordance with an embodiment of the inventive concept;

FIG. 3 is a cross-sectional view schematically illustrating a semiconductor device in accordance with an embodiment of the inventive concept;

FIG. 4A is a perspective view schematically illustrating a semiconductor device in accordance with an embodiment of the inventive concept;

FIG. 4B is a cross-sectional view schematically illustrating the a semiconductor device of FIG. 4A in accordance with an embodiment of the inventive concept;

FIG. 5 is a cross-sectional view schematically illustrating a semiconductor device in accordance with an embodiment of the inventive concept;

FIG. 6 is a cross-sectional view schematically illustrating a semiconductor device in accordance with an embodiment of the inventive concept;

FIGS. 7A to 7D are cross-sectional views illustrating a method of manufacturing an upper semiconductor package usable in a semiconductor device according to an embodiment of the inventive concept;

FIGS. 8A to 8H are cross-sectional views illustrating a method of manufacturing a lower semiconductor package and manufacturing a semiconductor device including the lower semiconductor package according to an embodiment of the inventive concept;

FIGS. 9A and 9B are cross-sectional views illustrating a method of manufacturing a semiconductor device in accordance with an embodiment of the inventive concept;

FIGS. 10A to 10I are cross-sectional views illustrating a method of manufacturing a lower semiconductor package and manufacturing a semiconductor device including the lower semiconductor package according to an embodiment of the inventive concept;

FIGS. 11A to 11H are cross-sectional views illustrating a method of manufacturing a lower semiconductor package and manufacturing a semiconductor device including the lower semiconductor package according to an embodiment of the inventive concept;

FIGS. 12A and 12B are cross-sectional views illustrating a method of manufacturing a semiconductor device according to an embodiment of the inventive concept;

FIG. 13 is a view illustrating a module having a semiconductor device according to an embodiment of the inventive concept;

FIG. 14 is a block diagram illustrating an electronic system including at least one of semiconductor devices according to an embodiment of the inventive concept;

FIG. 15 is a block diagram schematically illustrating an electronic system including at least one of semiconductor devices according to an embodiment of the inventive concept; and

FIG. 16 is a view schematically illustrating a mobile electronic device including at least one of semiconductor devices according to an embodiment of the inventive concept.

### DETAILED DESCRIPTION OF THE EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept while referring to the figures.

In the drawings, the sizes and relative sizes of layers and regions, and particularly, a conductive material, an adhesive, etc. may be exaggerated for clarity.

In the specification, some elements, and particularly, package bumps, a ground line, a signal line, a ground via, a signal via, etc. are exaggerated, simplified, and illustrated in a virtual shape so as to enable the easy understanding of the inventive concept.

Like reference numerals refer to like elements throughout. Therefore, although like reference numerals or similar reference numerals are not referred or described in a corresponding drawing, they may be described with reference to the other drawing. Also, although reference numeral is not illustrated, it may be described with reference to the other drawings.

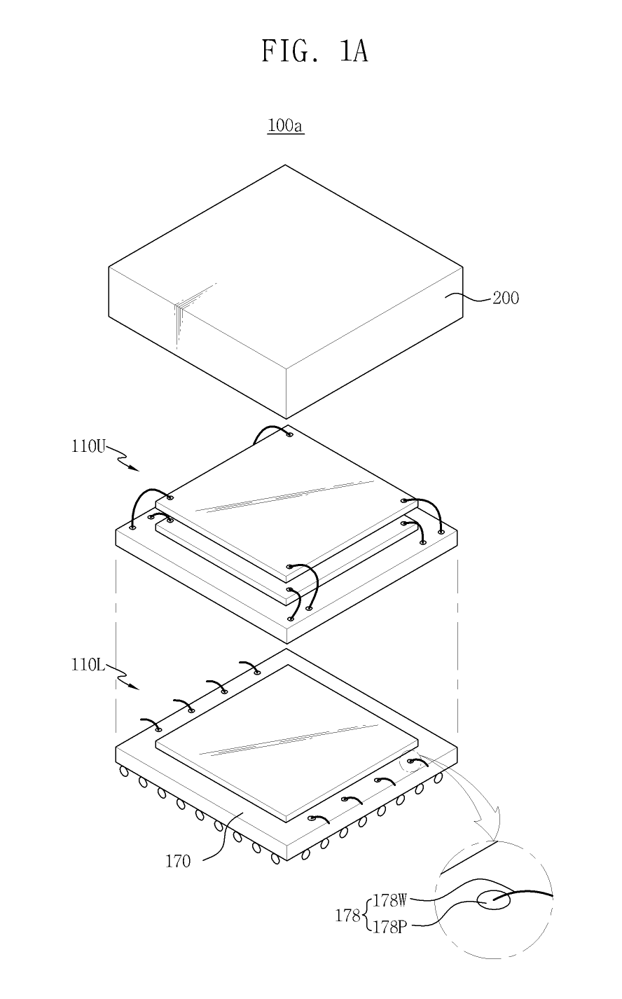

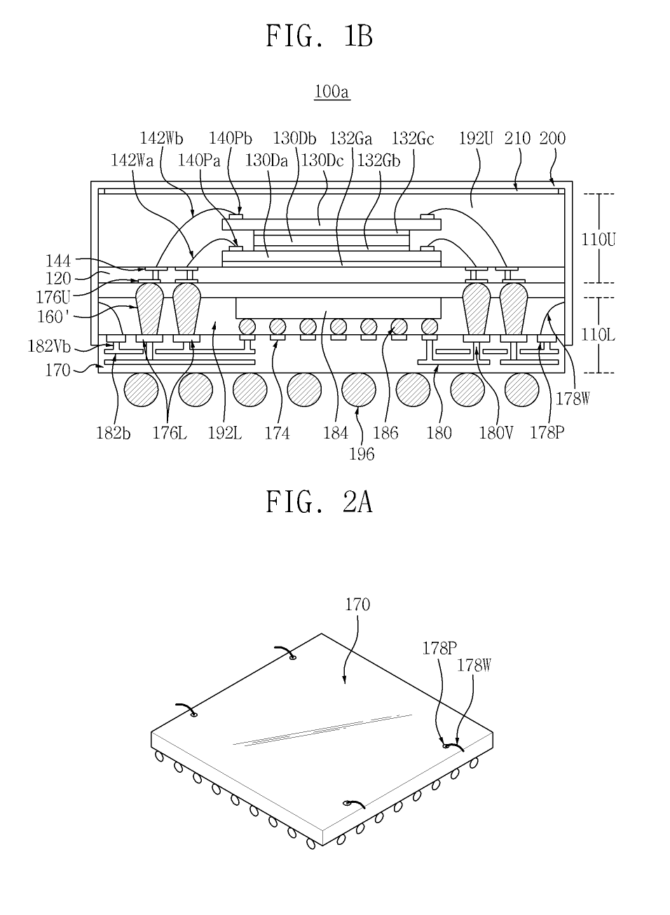

FIG. 1A is a perspective view schematically illustrating a semiconductor device 100a in accordance with an embodiment of the inventive concept. FIG. 1B is a longitudinal sectional view of the semiconductor device 100a of FIG. 1A in accordance with an embodiment of the inventive concept.

Referring to FIG. 1A, the semiconductor device 100a in accordance with the inventive concept includes a lower semiconductor package 110L, an upper semiconductor package 110U that is stacked on the lower semiconductor package 110L, a cover 200 that covers the lower semiconductor package 110L and the upper semiconductor package 110U, and a plurality of ground units 178 (178W and 178P).

The cover 200 shields electromagnetic interference (EMI) that occurs inside the semiconductor device 100a.

The ground units 178 (178P and 178W) may include a ground wire 178W and a ground wire pad 178P that are formed at a top of a lower substrate 170 of the lower semiconductor package 110L. The ground wire pad 178P and the ground wire 178W may electrically connect the cover 200 and the lower semiconductor package 110L. The ground wire pad 178P and the ground wire 178W may be arranged adjacent to a first side of a top portion of the lower substrate 170 and a second side of the top portion opposite to the first side.

Referring to FIG. 1B, the upper semiconductor package 110U of the semiconductor device 100a in accordance with the inventive concept may include an upper substrate 120, and first to third upper semiconductor chips 130Da to 130Dc that are stacked on a top of the upper substrate 120. Each of the first to third upper semiconductor chips 130Da to 130Dc may include a memory such as a dynamic random access memory (DRAM).

The upper substrate 120 may be a printed circuit board (PCB) including a multi-layer line. A plurality of upper bonding lands 144 may be formed at the top of the upper substrate 120, and a plurality of upper bump lands 176U may be formed at a bottom of the upper substrate 120.

First, second, and third adhesive layers 132Ga to 132Gc may be disposed between the upper substrate 120 and the first, second, and third upper semiconductor chips 130Da, Db, and 130Dc. Each of the first, second, and third adhesive layers 132Ga, Gb, and 132Gc may include a die attach film (DAF).

A bonding pad 140Pa may be formed at a top of the first upper semiconductor chip 130Da, and a bonding pad 140Pb may be formed at a top of the third upper semiconductor chip 130Dc. A plurality of bonding wires 142Wa and 142Wb that electrically connect the bonding pads 140Pa and 140Pb and the bonding lands 144 may be formed. The first to third upper semiconductor chips 130Da to 130Dc and the upper substrate 120 may be electrically connected through the bonding pads 140Pa and 140Pb, the bonding wires 142Wa and 142Wb, and the upper bonding lands 144.

An upper molding material 192U that surrounds the first to third upper semiconductor chips 130Da to 130Dc and the bonding wires 142Wa and 142Wb may be formed at the top of the upper substrate 120.

The lower semiconductor package 110L of the semiconductor device 100a in accordance with the inventive concept may include a lower substrate 170, a plurality of solder balls 196 that are formed at a bottom of the lower substrate 170, a lower semiconductor chip 184 that is mounted on the top of the lower substrate 170, a plurality of chip bumps 186 that electrically connect the lower semiconductor chip 184 and the lower substrate 170, and a lower molding material 192L that surrounds a side surface of the lower semiconductor chip 184. The lower semiconductor chip 184 may include a logic element such as a microprocessor.

The solder balls 196 may be disposed in a grid type at the bottom of the lower substrate 170, and the solder balls 196 may electrically connect the semiconductor device 100a to a module board or a main circuit board.

The lower substrate 170 and the lower semiconductor chip 184, for example, may be bonded by a flip chip scheme. The lower substrate 170 may include a plurality of lower bump lands 176L that are formed at the top thereof, and a plurality of chip bump lands 174 that contact the chip bump 186.

The plurality of ground wires 178W that are attached to the ground wire pads 178P and the ground wire pads 178P may be formed at the top of the lower substrate 170. For example, a first end portion of the ground wire 178W may be attached to the ground wire pad 178P, and a second end portion of the ground wire 178W may be exposed to a side surface of the lower molding material 192L to be connected to an external potential.

The lower substrate 170 may include a plurality of signal lines 180, ground lines 182b, signal vias 180V, and ground vias 182Vb that are formed therein. The signal via 180V may be electrically connected to the signal line 180, and the ground via 182Vb may be electrically connected to the ground line 182b. Additionally, the signal vias 180V may be physically and electrically connected to the chip bump lands 174, the lower bump lands 176L, and the solder balls 186. The ground vias 182Vb may be physically and electrically connected to the chip bump lands 174, the lower bump lands 176L, the solder balls 186, and the ground wire pads 178P.

The semiconductor device 100a in accordance with the inventive concept may include a plurality of package bumps 160′ that electrically connect the upper semiconductor package 110U and the lower semiconductor package 110L. The package bumps 160′ may be formed between the upper bump lands 176U of the upper substrate 120 and the lower bump lands 176L of the lower substrate 170, respectively.

The cover 200 may cover the upper and lower semiconductor packages 110U and 110L and may be a conductive member. The cover 200 may have a shape that covers the upper and lower semiconductor packages 110U and 110L, for example, a hexahedral shape with one opened surface. An adhesive 210 may be disposed between the upper molding material 192U and the cover 200. For example, the adhesive 210 may be an insulating adhesive tape, and attach the cover 200 to the stacked upper and lower semiconductor packages 110U and 110L.

The cover 200 may contact a second end portion of the ground wire 178W that is exposed to a side surface of the lower molding material 192L. Therefore, the cover 200 may be grounded to an outside thereof, for example, an external potential, through the ground wire 178W and the ground wire pad 178P, and thus, the EMI shielding effect of the semiconductor device 100a can be improved. Additionally, when the cover 200 is a conductive metal member, the cover 200 may be used as an element that dissipates heat in the semiconductor device 100 to the outside.

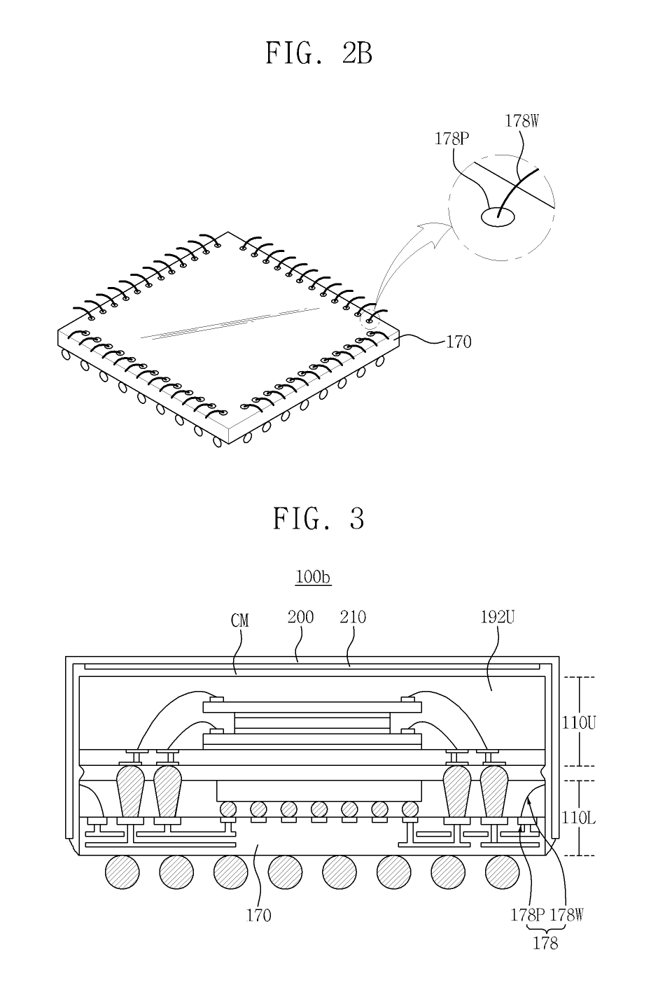

FIGS. 2A and 2B are perspective views illustrating a structure of the ground wire 178W of the semiconductor device 100a of FIGS. 1A and 1B according to an embodiment of the present general inventive concept.

Referring to FIG. 2A, the ground wire pads 178P and the ground wires 178W may be formed at corner areas of the lower substrate 170.

Referring to FIG. 2B, the ground wire pad 178P and the ground wires 178W may be arranged adjacent to corresponding sides, for example, first to fourth sides, of the top of the lower substrate 170. The ground wire pad 178P and the ground wire 178W may be formed on two opposite sides of the top 170 of the lower substrate 170. The ground wire pads 178P and the ground wire 178W may be formed on more than two sides of a plurality of sides of the lower substrate 170.

FIG. 3 is a longitudinal sectional view schematically illustrating a configuration of a semiconductor device 100b in accordance with an embodiment of the inventive concept.

Referring to FIG. 3, the semiconductor device 100b in accordance with an embodiment of the inventive concept includes an upper semiconductor package 110U, a lower semiconductor package 110L, a cover 200 that covers the upper and lower semiconductor packages 110U and 110L, a conductive material CM that is disposed between the upper and lower semiconductor packages 110U and 110L and the cover 200, and a plurality of ground units 178 (178W and 178P) that are formed at the lower semiconductor package 110L.

The conductive material CM may be a resin including a plurality of conductive metal balls.

An adhesive 210 may be disposed between the conductive material CM and the cover 200. The adhesive 210 may be disposed between the cover 200 and the conductive material CM that is disposed on a top of an upper molding material 192U.

The ground units 178 (178P and 178W) may include a ground wire pad 178P that is formed at a top of a lower substrate 170, and a ground wire 178W that has a first end portion attached to the ground wire pad 178P and a second end portion contacting the conductive material CM.

The conductive material CM may be attached to and contact the ground wire 178W and the cover 200, and thus may electrically connect the ground wire 178P and the cover 200. Therefore, the cover 200 is grounded to the outside through the conductive material CM, the ground wire pad 178P, and the ground wire 178W, thus improving the EMI shielding effect of the semiconductor device 100b. The conductive material CM may have a portion to protrude toward a space between the upper and lower semiconductor packages 110U and 110L as illustrated in FIG. 3.

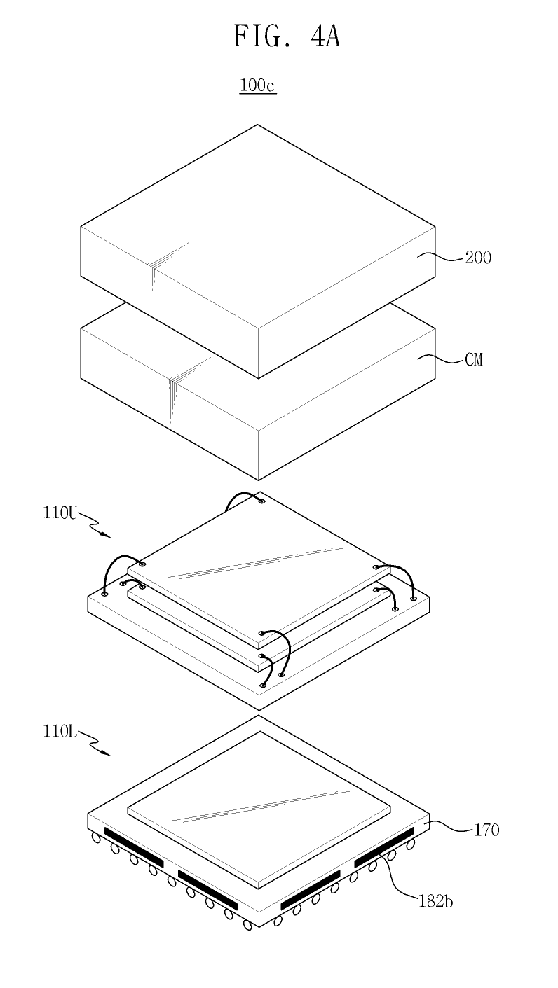

FIG. 4A is a perspective view schematically illustrating a structure of a semiconductor device 100c in accordance with an embodiment of the inventive concept. FIG. 4B is a longitudinal sectional view schematically illustrating a structure of a semiconductor device in accordance with an embodiment of the inventive concept.

Referring to FIGS. 4A and 4B, the semiconductor device 100c in accordance with the inventive concept includes an upper semiconductor package 110U and a lower semiconductor package 110L that are stacked vertically, a cover 200 that covers the upper and lower semiconductor packages 110U and 110L, a conductive material CM that is disposed between the upper and lower semiconductor packages 110U and 110L and the cover 200, and a ground line 182b that is formed at the lower semiconductor package 110L.

The ground line 182b may be formed inside a lower substrate 170 of the lower semiconductor package 110L, and one end portion of the ground line 182b may be exposed to a side surface of the lower substrate 170. The conductive material CM may contact the ground line 182b and the cover 200. The conductive material CM contacts the ground line 182b and the cover 200, and thus electrically connects the ground line 182b and the cover 200.

Therefore, the cover 200 is grounded to the outside through the conductive material CM and the ground line 182b, thus improving the EMI shielding effect of the semiconductor device 100c.

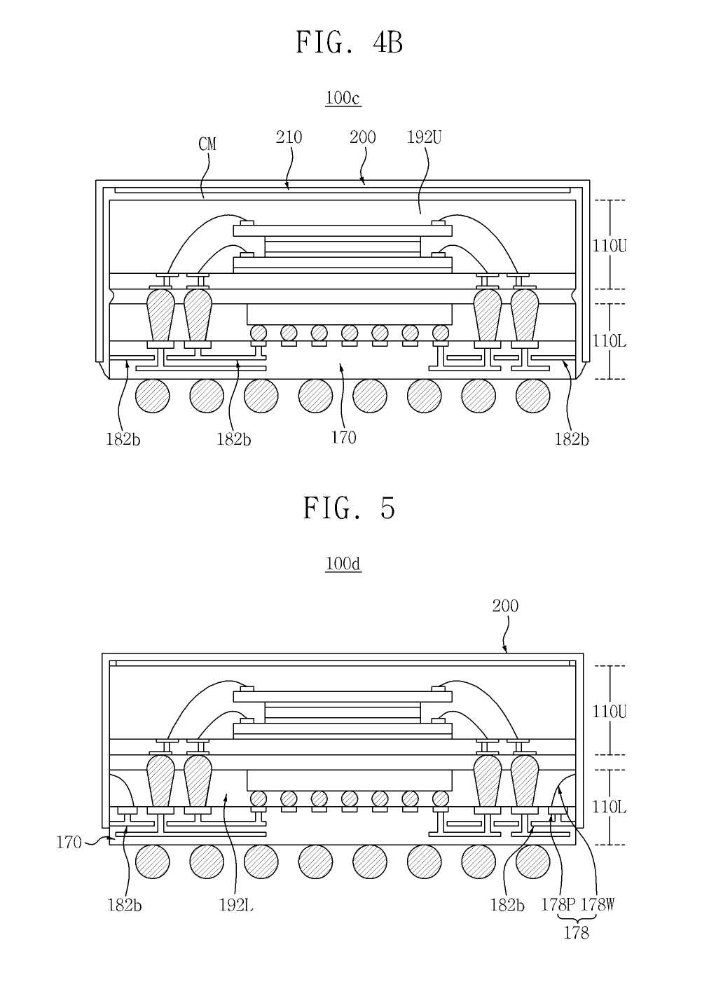

FIG. 5 is a longitudinal sectional view schematically illustrating a configuration of a semiconductor device 100d in accordance with an embodiment of the inventive concept.

Referring to FIG. 5, the semiconductor device 100d in accordance with the inventive concept includes an upper semiconductor package 110U and a lower semiconductor package 110L that are stacked vertically, a cover 200 that covers the upper and lower semiconductor packages 110U and 110L, and a plurality of ground units 178P, 178W and 182b that are formed at the lower semiconductor package 110L.

The ground units 178P, 178W and 182b may include a ground wire pad 178P that is formed at a top of the lower substrate 170, a ground wire 178W that has a first end portion attached to the ground wire pad 178P and a second end portion exposed to a side surface of the lower molding material 192L, and a ground line 182b that is exposed to a side surface of the lower substrate 170.

The cover 200 covers the upper and lower semiconductor packages 110U and 110L and may simultaneously contact the second end portion of the ground wire 178W and the ground line 182b.

Therefore, the cover 200 is grounded to an outside thereof through the ground wire 178W, the ground wire pad 178P, and the ground line 182b, thus improving the EMI shielding effect of the semiconductor device 100d. The cover 200 may have a portion or a distal end portion extended to contact one or more portions of the ground line 182b which is exposed from a surface of the lower substrate 170.

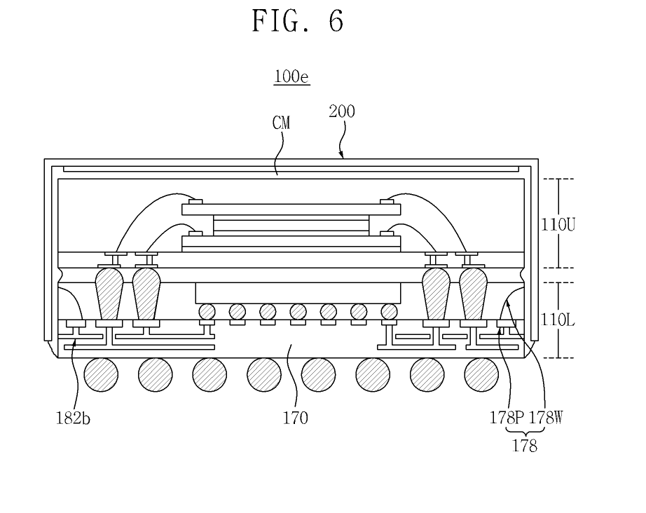

FIG. 6 is a longitudinal sectional view schematically illustrating a semiconductor device 100e in accordance with an embodiment of the inventive concept.

Referring to FIG. 6, the semiconductor device 100e in accordance with the inventive concept includes an upper semiconductor package 110U and a lower semiconductor package 110L that are stacked vertically, a cover 200 that covers the upper and lower semiconductor packages 110U and 110L, a conductive material CM that is disposed between the upper and lower semiconductor packages 110U and 110L and the cover 200, and a plurality of ground units 178 (178P, 178W and 182b) that are formed at the lower semiconductor package 110L.

The ground units 178 (178P, 178W and 182b) may include a ground line 182b that is exposed to a lower substrate 170 of the lower semiconductor package 110L, a ground wire pad 178P that is formed at a top of the lower substrate 170, and a ground wire 178W that has a first end portion attached to the ground wire pad 178P and a second end portion was in contact with the conductive material CM.

The cover 200 may be electrically connected to the ground wire 178W, the ground wire pad 178P, and the ground line 182b through the conductive material CM.

Therefore, the cover 200 is grounded to the outside through the conductive material CM, the ground wire 178W, the ground wire pad 178P, and the ground line 182b, thus improving the EMI shielding effect of the semiconductor device 100e. The conductive material CM may have a portion or a distal end portion extended to contact one or more portions of the ground line 182b which is exposed from a surface of the lower substrate 170

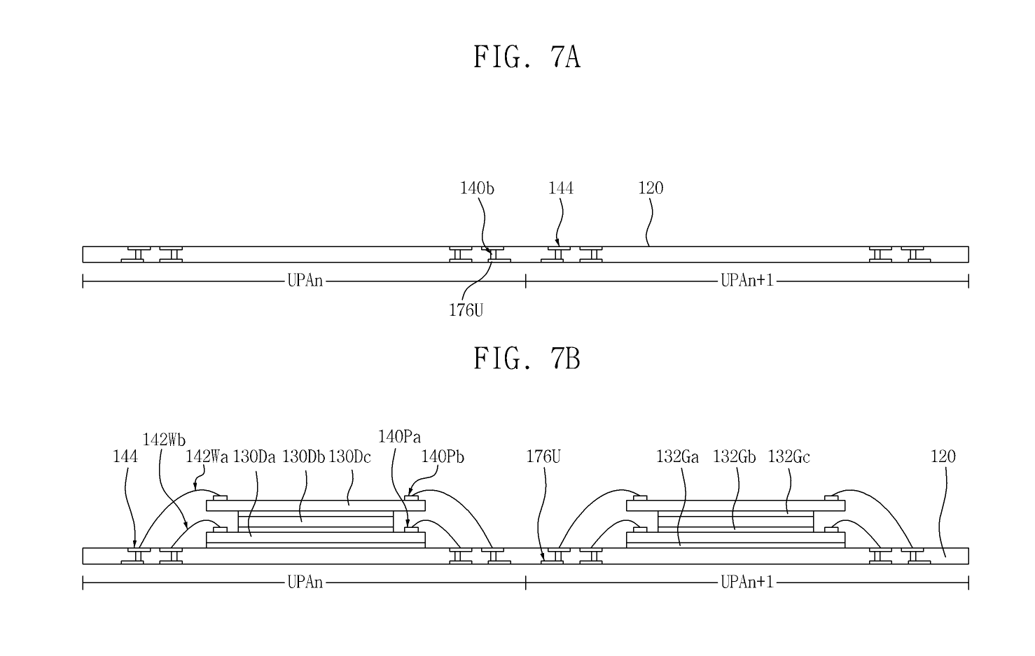

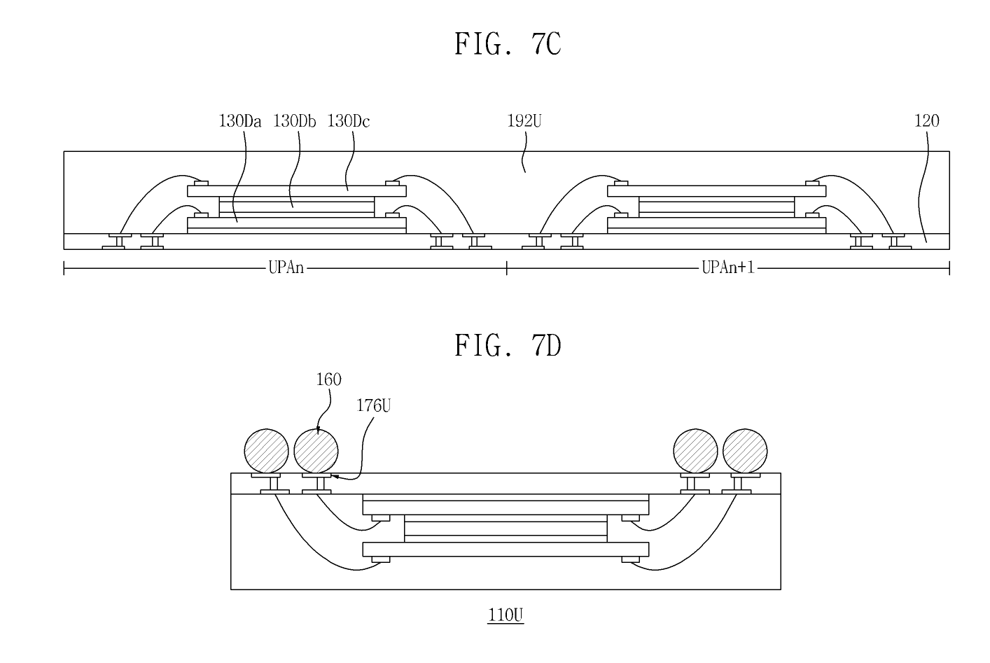

FIGS. 7A to 7D are longitudinal sectional views for describing a method of manufacturing an upper semiconductor package in accordance with an embodiment of the inventive concept.

Referring to FIG. 7A, an upper substrate 120 with a plurality of upper package areas UPAn and UPAn+1 defined therein is prepared. Each of the package areas UPAn and UPAn+1 may include a plurality of bonding lands 144 and upper bump lands 176U. The bonding lands 144 and the upper bump lands 176U may be formed at an upper surface and lower surface of the upper substrate 120, respectively.

Referring to FIG. 7B, in each of the package areas UPAn and UPAn+1, a plurality of chips, for example, first, second, and third upper semiconductor chips 130Da, 130Db, and 130Dc, are stacked on a top of the upper substrate 120. A first insulating adhesive layer 132Ga may be disposed between the first upper semiconductor chip 130Da and the upper substrate 120, and second and third insulating adhesive layers 130Gb and 130Gc may be disposed between the adjacent upper semiconductor chips 130Da to 130Dc. A plurality of bonding wires 142Wa and 142Wb that connect the bonding pads 140Pa and 140Pb and the bonding lands 144 may be formed.

Referring to FIG. 7C, an upper molding material 192U that covers the upper substrate 120 including a plurality of chips, for example, the first, second, and third upper semiconductor chips 130Da, 130Db, and 130Dc may be formed.

The upper molding material 192U may include an epoxy molding compound (EMC). The upper substrate 120 may be separated separately for each of the package areas UPAn and UPAn+1, and divided into a plurality of upper semiconductor packages 110U. The separating process may include a sawing process or a cutting process.

Referring to FIG. 7D, the upper semiconductor package 110U may be turned over, and an upper package bump 160 may be formed at a bottom of each of the upper bump lands 176U. The package bump 160 may be formed by a soldering process. Accordingly, the upper semiconductor package 110U in accordance with the inventive concept can be finished.

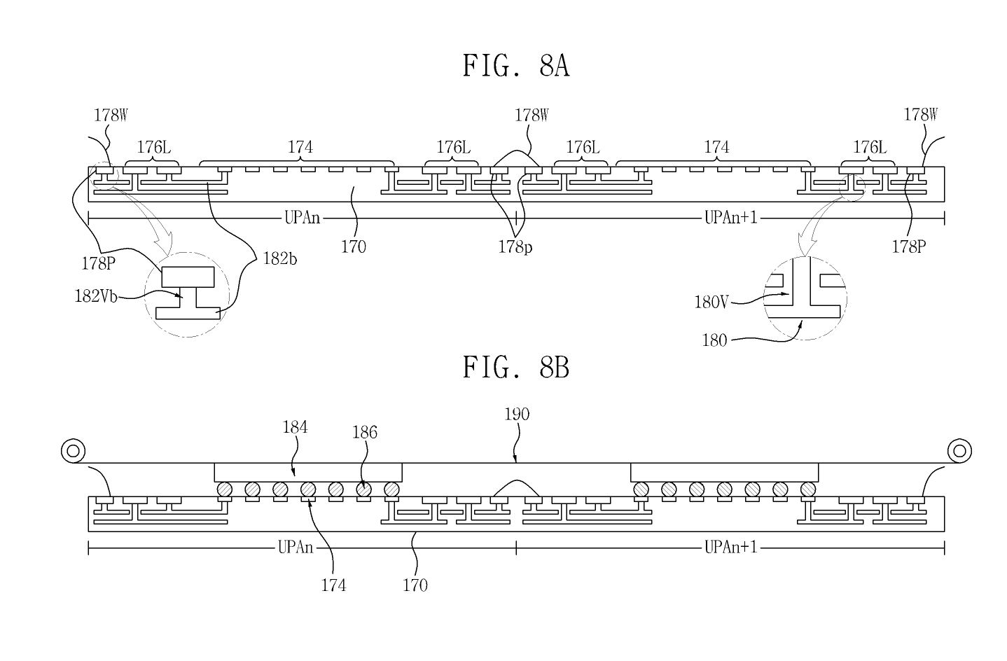

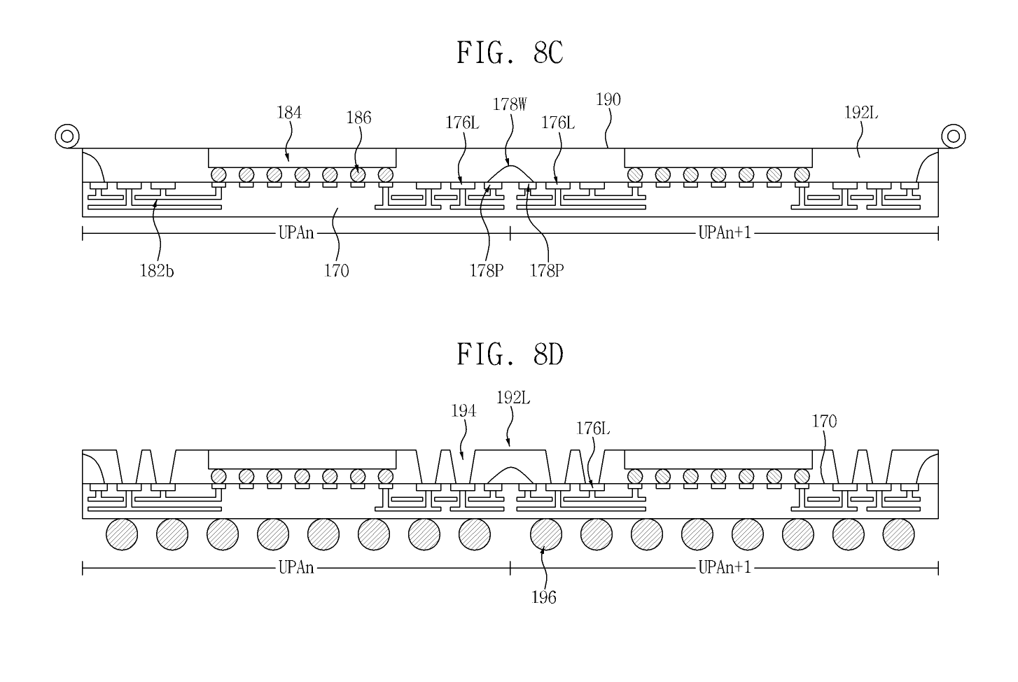

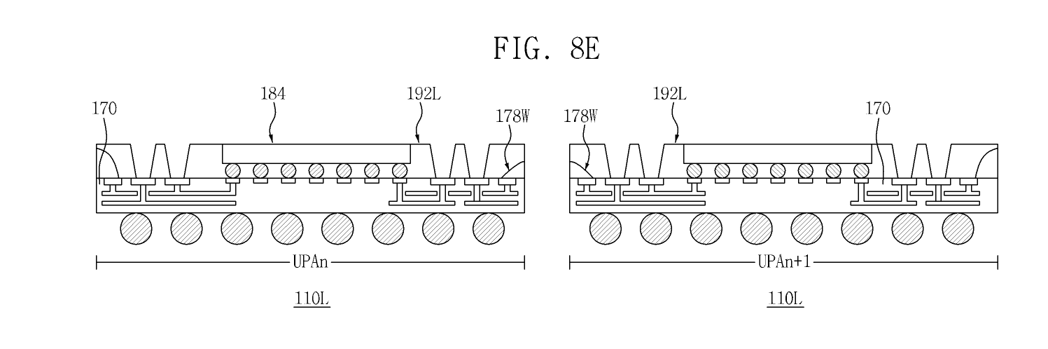

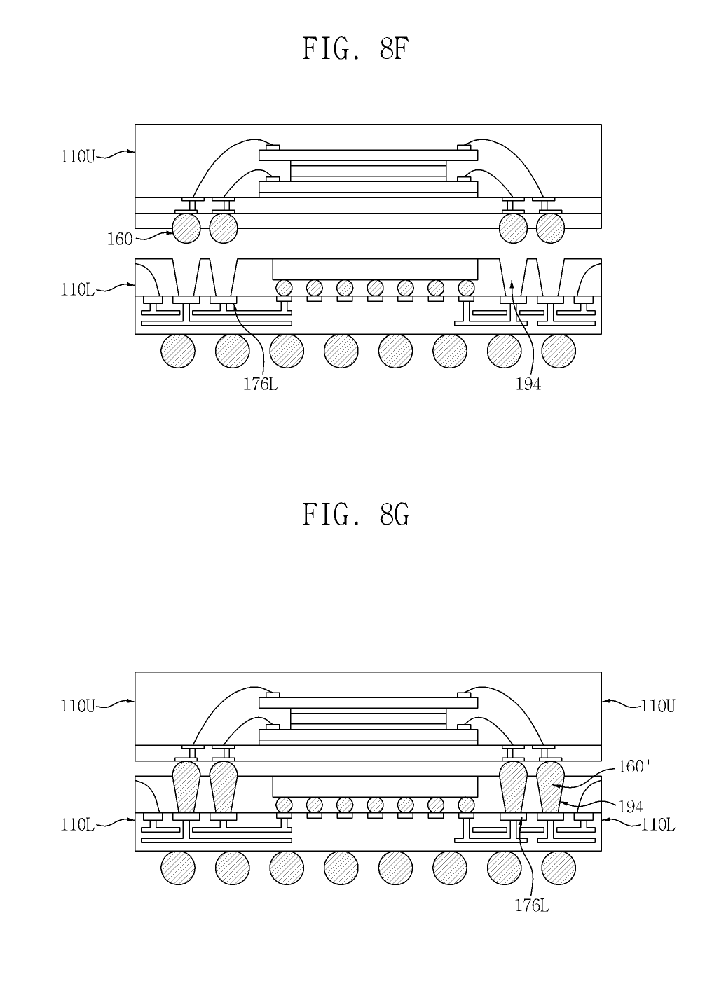

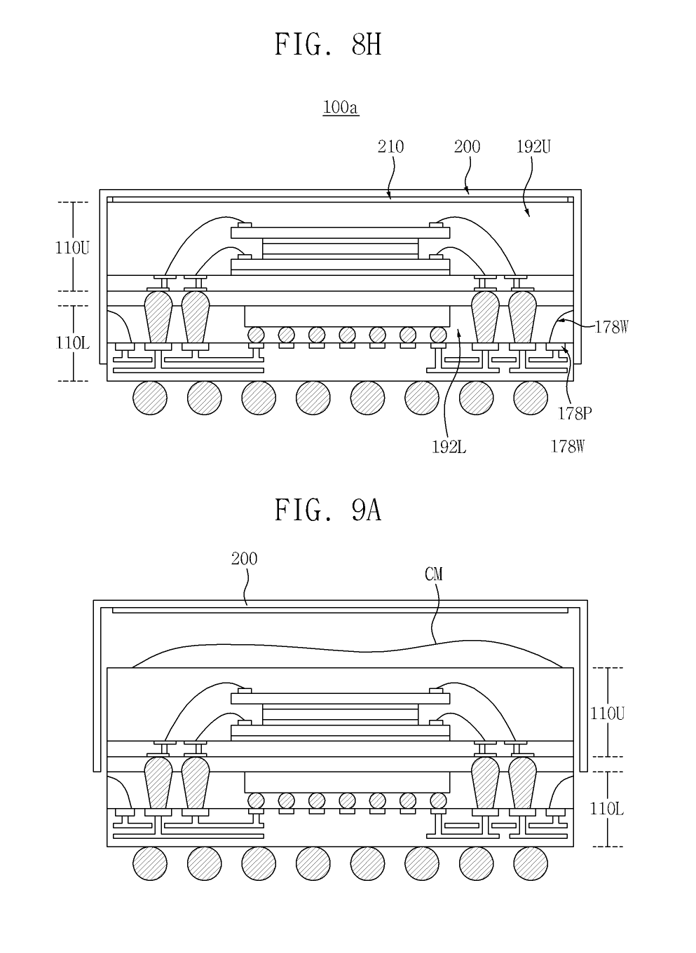

FIGS. 8A to 8H are longitudinal sectional views illustrating a method of manufacturing a lower semiconductor package in accordance with an embodiment of the inventive concept and a method of manufacturing a semiconductor device including the lower semiconductor package.

Referring to FIG. 8A, a lower substrate 170 with a plurality of lower package areas LPAn and LPAn+1 defined therein is prepared. The lower substrate 170 may internally include a plurality of signal lines 180, ground lines 182b, signal vias 180V, and ground vias 182Vb. The signal via 180V may be electrically connected to the signal line 180, and the ground via 182Vb may be electrically connected to the ground line 182b. Each of the lower package areas LPAn and LPAn+1 may include a plurality of chip bump lands 174, lower bump lands 176L, and ground wire pads 178P that are formed at a top of the lower substrate 170. In the process to be described below, the lower bump land 176L contacts the upper package bump 160 of the upper semiconductor package 110U, and thus may be formed around the lower package areas LPAn and LPAn+1. The lower bump land 176L may be disposed to be separated from the chip bump lands 174.

A plurality of ground wires 178W, which are simultaneously attached to the adjacent ground wire pads 178P that are formed in each of the adjacent lower package areas LPAn and LPAn+1, may be formed. As described in FIGS. 1A, 2A and 2B, the ground wires 178W may be arranged adjacent to a first side of a top of the lower substrate 170 and a second side opposite to the first side, arranged at respective corners of the top of the lower substrate 170, and arranged adjacent to first to fourth sides of the top of the lower substrate 170. The ground wire 178W may include gold (Au) or aluminum (Al).

Referring to FIG. 8B, a lower semiconductor chip 184 is mounted on each of the lower package areas LPAn and LPAn+1 that are defined in the lower substrate 170. A plurality of chip bumps 186 may be formed at a bottom of the lower semiconductor chip 184. The chip bumps 186 of the lower semiconductor chip 184 may be physically and electrically attached and connected to the chip bump lands 174 of the lower substrate 170 through a reflow process. A molding control film 190 is disposed on the lower semiconductor chips 184. The molding control film 190 may be disposed closely to a top of each of the lower semiconductor chips 184. A space may be secured between the molding control film 190 and the lower substrate 170. The molding control film 190 may be a tape of cellulose, acetate, polyvinyl, polyurethane, or the other various materials.

Referring to FIG. 8C, a lower molding material 192L is charged (filled) into the space that has been secured between the lower substrate 170 and the molding control film 190. The lower molding material 192L may cover the lower bump lands 176L, the ground wire pads 178P, and the ground wires 178W, surround a side surface of the lower semiconductor chip 184, and fill a lower area of the molding control film 190. Alternatively, an area with the chip bumps 186 disposed therein may be filled with an underfill material, in which case an area outside the underfill material may be filled with the lower molding material 192L. The lower molding material 192L may include an EMC. Subsequently, the molding control film 190 may be removed.

Referring to FIG. 8D, a laser drilling process that exposes surfaces of the lower bump lands 176L may be performed. By the laser drilling process, a portion of the lower molding material 192L may be selectively removed, and an opening 194 may be formed to expose an entirety or portion of the surface of the lower bump land 176L. A plurality of solder balls 196 may be formed at the bottom of the lower substrate 170. The solder balls 196 may be formed by a soldering process. The order of the laser drilling process and soldering process may be switched.

Referring to FIG. 8E, the lower substrate 170 including the lower semiconductor chips 184 and the lower molding material 192L is separated for each of the lower package areas LPAn and LPAn+1. A plurality of lower semiconductor packages 110L may be formed by the separating process. A sawing process, a drilling process, and a cutting process may be used as the separating process. Through the separating process, a ground wire 178W formed over the adjacent lower package areas LPAn and LPAn+1 may be cut, and thus, the cut surface of the ground wire 178W may be exposed to a side surface of the lower molding material 192L.

Referring to FIG. 8F, a process is performed to stack the upper semiconductor package 110U formed according to a process descried in FIGS. 7A to 7D on the lower semiconductor package 110L. The package bump 160 (connection bump) of the upper semiconductor package 110U undergoes a process in which the package bump 160 is dipped in a solder flux, and contacts the lower bump land 176L of the lower semiconductor package 110L through the opening 194 of the lower semiconductor package 110L.

Referring to FIG. 8G, the upper semiconductor package 110U and the lower semiconductor package 110L may be stacked. In this process, the package bump 160 may be heated and reflowed in the opening 194 of the lower semiconductor package 110L, and connected to the lower bump land 176L physically and electrically such that the package bump 160′ can be formed.

Referring to FIG. 8H, a process in which the cover 200 covers the stacked upper and lower semiconductor packages 110U and 110L and an attachment therebetween is performed may be performed. The cover 200 may be formed as a conductive member, and have a shape that is capable of covering the upper and lower semiconductor packages 110U and 110L, for example, a hexahedral shape with one opened surface. An adhesive 210 may be formed at an inner surface of the cover 200 contacting a top of the upper molding material 192U of the upper semiconductor package 110U. When a covering process using the cover 200 is completed, the cover 200 may contact the ground wire 178W that is exposed to a side surface of the lower molding material 192L.

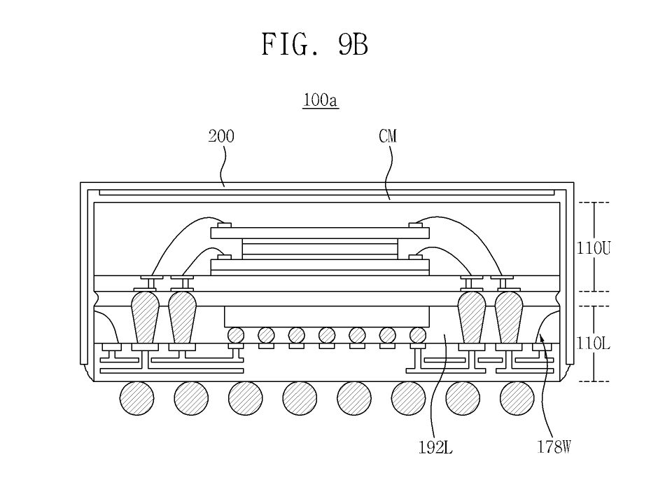

FIGS. 9A and 9B are longitudinal sectional views for describing a method of manufacturing a semiconductor device in accordance with an embodiment of the inventive concept. A method of manufacturing upper and lower semiconductor packages is the same as the descriptions of FIGS. 8A to 8G, and thus, description thereof is not provided.

Referring to FIG. 9A, a conductive material CM may be provided to a top of stacked upper and lower semiconductor packages 110U and 110L by a defined amount. The conductive material CM may have flux, and may be a resin including a plurality of conductive metal balls. A process in which a cover 200 covers the stacked upper and lower semiconductor packages 110U and 110L may be performed.

Referring to FIG. 9B, a process is performed to provide the cover 200 to cover the upper and lower semiconductor packages 110U and 110L and also to provide an attachment therebetween. When a process of covering the stacked upper and lower semiconductor packages 110U and 110L by applying a certain pressure to the cover 200 is performed, the conductive material CM may be spread to a top and entire side surface of each of the stacked upper and lower semiconductor packages 110U and 110L. Therefore, the conductive material CM may be disposed between the stacked upper and lower semiconductor packages 110U and 110L and the cover 200, and contact a ground wire 178W that is exposed to the side surface of the lower molding material 192L.

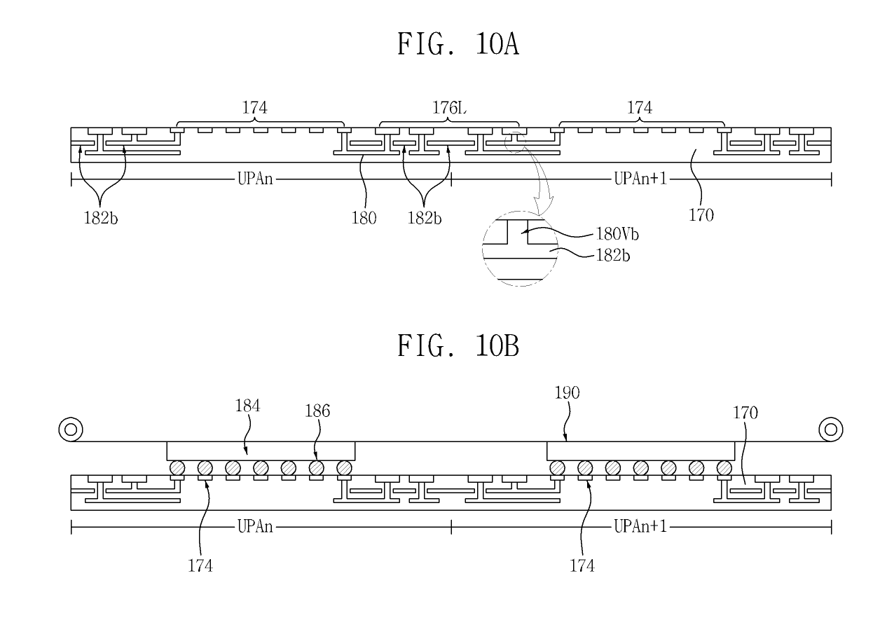

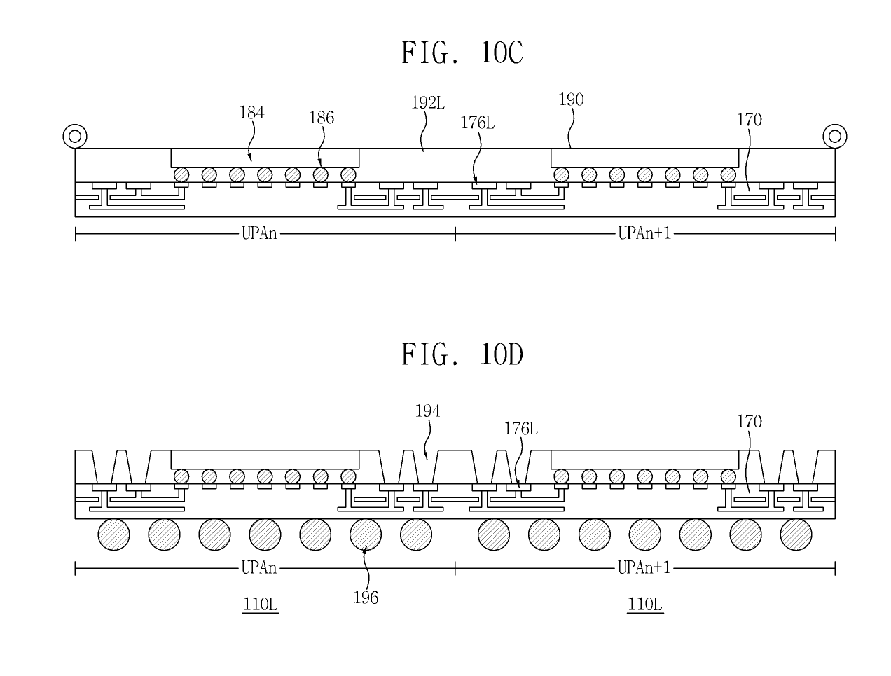

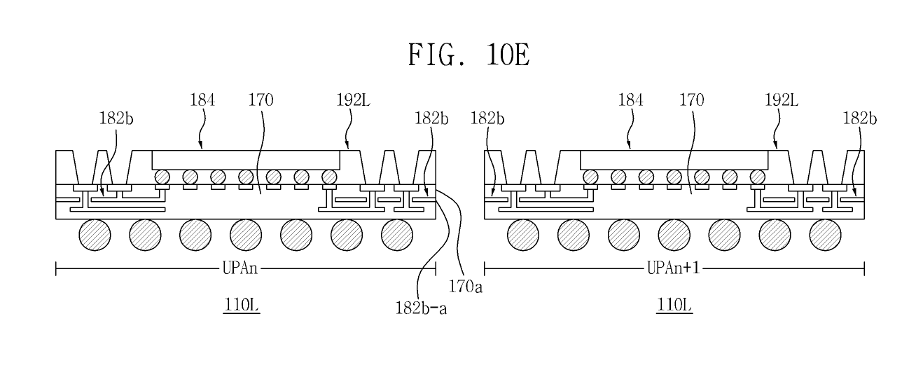

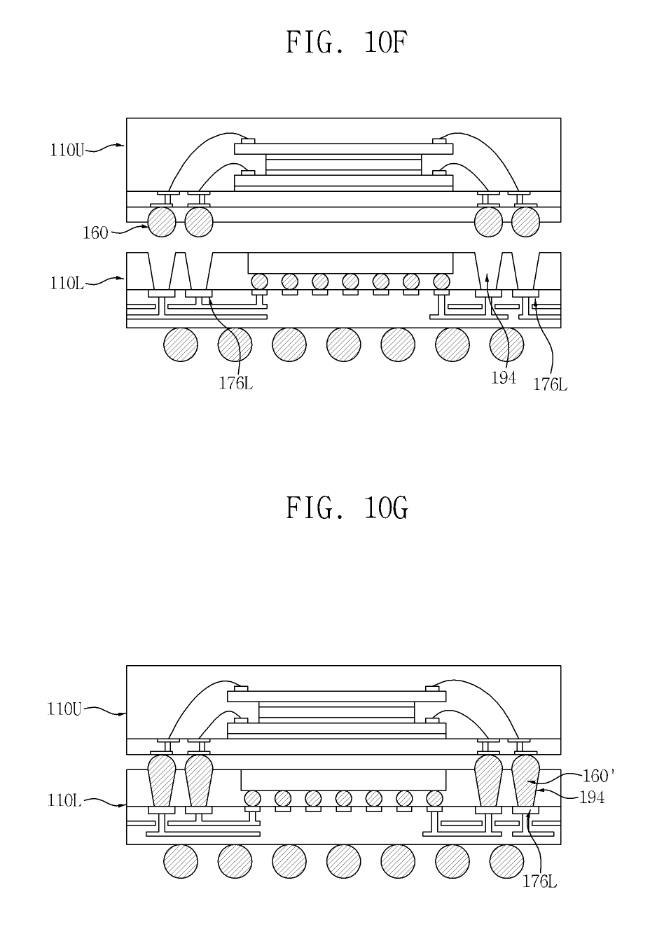

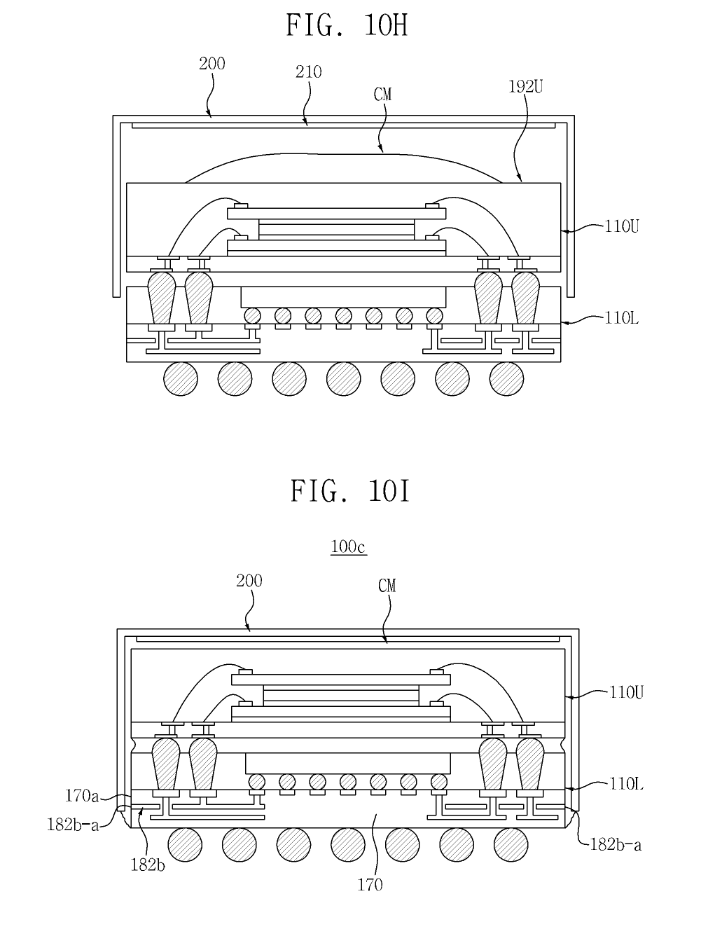

FIGS. 10A to 10I are longitudinal sectional views for describing a method of manufacturing a lower semiconductor package in accordance with an embodiment of the inventive concept and a method of manufacturing a semiconductor device including the lower semiconductor package.

Referring to FIG. 10A, a lower substrate 170 with a plurality of lower package areas LPAn and LPAn+1 defined therein is prepared. The lower substrate 170 may internally include a plurality of signal lines 180, ground lines 182b, signal vias 180V, and ground vias 182Vb. The signal vias 180V may be electrically connected to the signal lines 180, and the ground vias 182Vb may be electrically connected to the ground lines 182b. One or more portions of the ground line 182b may be formed over the adjacent lower package areas LPAn and LPAn+1. Each of the lower package areas LPAn and LPAn+1 may include a plurality of chip bump lands 174 and lower bump lands 176L.

Referring to FIG. 10B, a lower semiconductor chip 184 is mounted on each of the lower package areas LPAn and LPAn+1. A plurality of chip bumps 186 may be formed at a bottom of the lower semiconductor chip 184. The chip bumps 186 of the lower semiconductor chip 184 may be physically and electrically connected to the chip bump lands 174 through a reflow process. A molding control film 190 is disposed on the lower semiconductor chips 184.

Referring to FIG. 10C, a lower molding material 192L is charged (filled) into a space that is secured between the lower substrate 170 and the molding control film 190. The lower molding material 192L may cover the lower bump lands 176L, surround a side surface of each of the lower semiconductor chips 184, and fill a lower area of the molding control film 190. Alternatively, an area with the chip bumps 186 disposed therein may be filled with an underfill material, in which case an area outside the underfill material may be filled with the lower molding material 192L.

Referring to FIG. 10D, the molding control film 190 may be removed, and a laser drilling process that exposes surfaces of the lower bump lands 176L may be performed. By the laser drilling process, a portion of the lower molding material 192L may be selectively removed, and a plurality of openings 194 that expose an entirety or portion of the surface of the lower bump land 176L may be formed. A plurality of solder balls 196 may be formed at the bottom of the lower substrate 170.

Referring to FIG. 10E, the lower substrate 170 including the lower semiconductor chips 184 and the lower molding material 192L is separated for each of the lower package areas LPAn and LPAn+1. A plurality of lower semiconductor packages 110L may be formed by the separating process. Through the separating process, a ground line 182b disposed between the adjacent lower package areas LPAn and LPAn+1 may be separated, and thus, a cut surface (or end surface) 182b-a of the ground line 182b may be exposed to a side surface 170a of the lower substrate 170.

Referring to FIG. 10F, a process in which the upper semiconductor package 110U illustrated in FIG. 7D is stacked on the lower semiconductor package 110L is performed. The package bump 160 (connection bump) of the upper semiconductor package 110U undergoes a process in which the package bump 160 is dipped in a solder flux, and contacts the lower bump land 176L of the lower semiconductor package 110L through the opening 194 of the lower semiconductor package 110L.

Referring to FIG. 10G, a process in which the upper semiconductor package 110U and the lower semiconductor package 110L are stacked is performed. In this process, the package bump 160′ (connection bump) may be formed by heating and reflowing the package bump 160 in the opening 194 of the lower semiconductor package 110L, and connected to the lower bump land 176L.

Referring to FIG. 10H, a conductive material CM may be provided on a top of the upper molding material 192U of each of the stacked upper and lower semiconductor packages 110U and 110L by a defined amount. For example, the conductive material CM may have flux, and may be a resin including a plurality of conductive metal balls. A process in which a cover 200 covers the stacked upper and lower semiconductor packages 110U and 110L may be performed. The cover may include an adhesive 210 formed at an inner surface thereof contacting the upper molding material 192U.

Referring to FIG. 10I, a process in which the cover 200 covers the stacked upper and lower semiconductor packages 110U and 110L and an attachment therebetween is performed may be performed. When a process of covering the stacked upper and lower semiconductor packages 110U and 110L by applying a certain pressure to the cover 200 is performed, the conductive material CM may be spread to a side surface and entire top of each of the stacked upper and lower semiconductor packages 110U and 110L. Therefore, the conductive material CM may be disposed between the stacked upper and lower semiconductor packages 110U and 110L and the cover 200, and electrically and physically contact one or more end portions 182b-a of a ground line 182b that is exposed to a side surface 170a of the lower substrate 170.

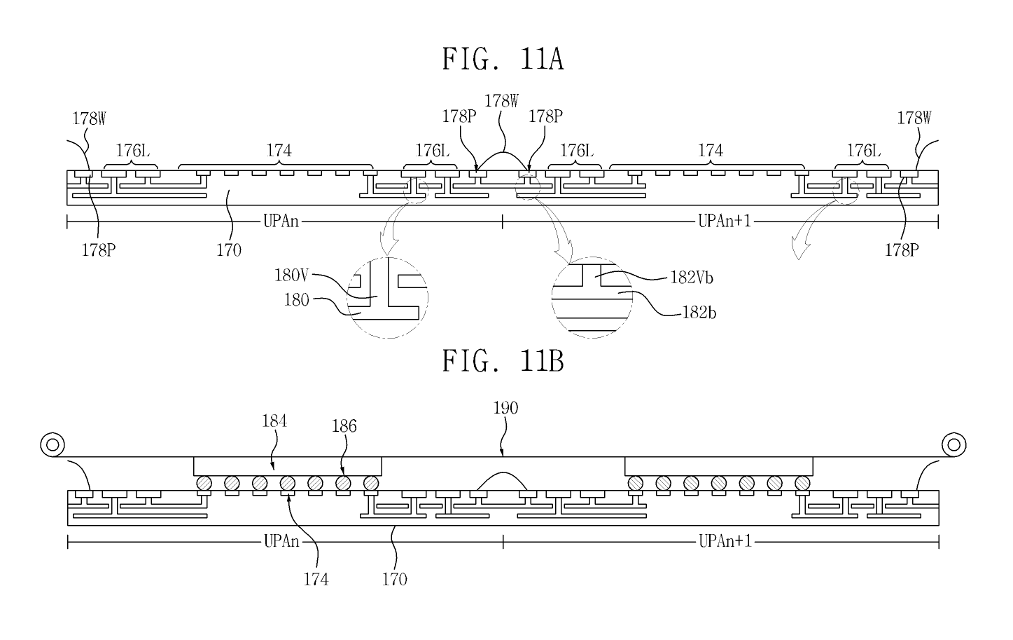

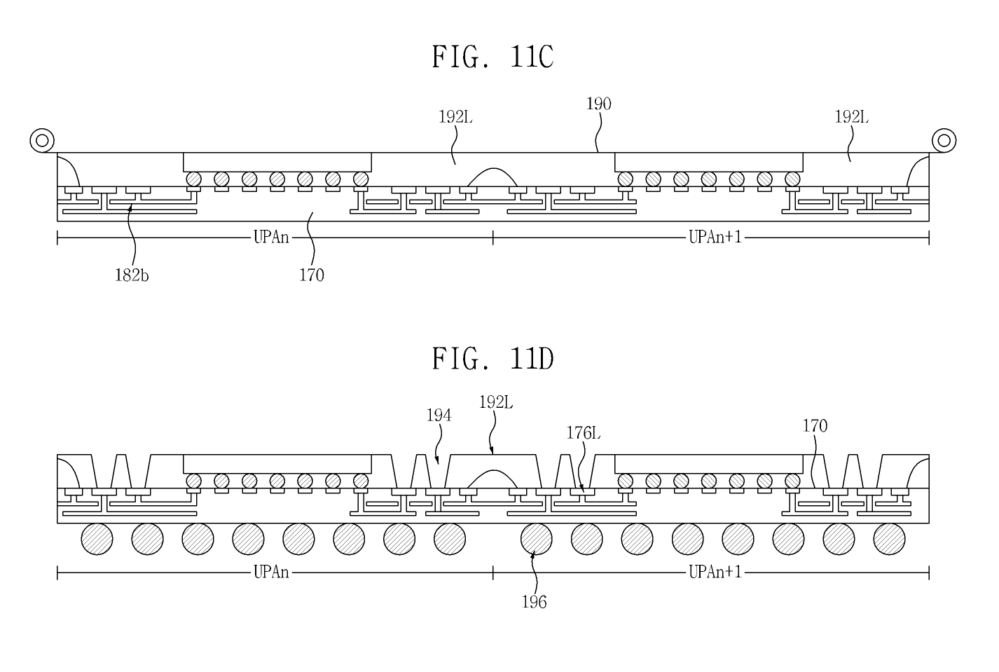

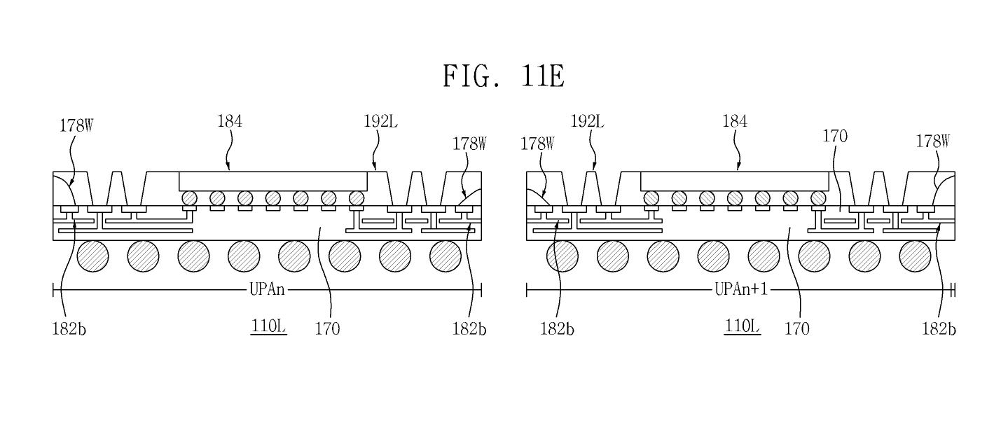

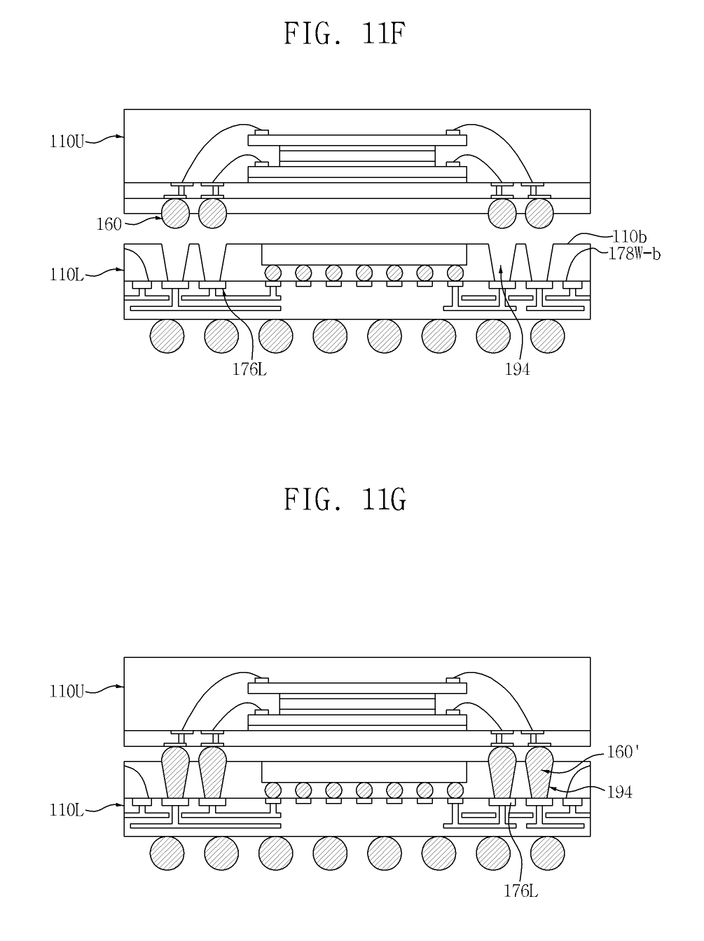

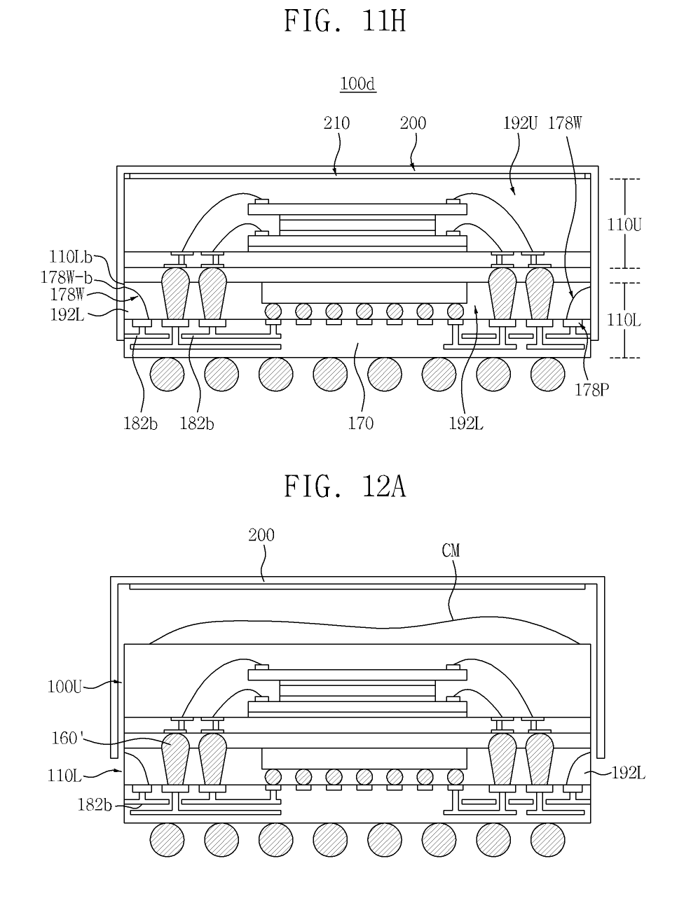

FIGS. 11A to 11H are longitudinal sectional views for describing a method of manufacturing a lower semiconductor package in accordance with an embodiment of the inventive concept and a method of manufacturing a semiconductor device including the lower semiconductor package.

Referring to FIG. 11A, a lower substrate 170 with a plurality of lower package areas LPAn and LPAn+1 defined therein is prepared. The lower substrate 170 may internally include a plurality of signal lines 180, ground lines 182b, signal vias 180V, and ground vias 182Vb. The signal via 180V may be electrically connected to the signal line 180, and the ground via 182Vb may be electrically connected to the ground line 182b. The ground line 812b may be formed over the adjacent semiconductor package areas LPAn and LPAn+1.

In each of the lower package areas LPAn and LPAn+1, a plurality of chip bump lands 174, lower bump lands 176L electrically connected to the signal vias 180V, and ground wire pads 178P electrically connected to the ground vias 182Vb may be formed at a top of the lower substrate 170. A plurality of ground wires 178W, which are simultaneously attached to the adjacent ground wire pads 178P respectively formed in each of the adjacent lower package areas LPAn and LPAn+1, may be formed.

Referring to FIG. 11B, a lower semiconductor chip 184 is mounted on each of the lower package areas LPAn and LPAn+1 that are defined in the lower substrate 170. A molding control film 190 may be disposed on a top of each of the lower semiconductor chips 184. A space may be secured between the molding control film 190 and the lower substrate 170.

Referring to FIG. 11C, a lower molding material 192L is charged (filled) into the space that has been secured between the lower substrate 170 and the molding control film 190.

Referring to FIG. 11D, a laser drilling process exposing surfaces of the lower bump lands 176L may be performed. By the laser drilling process, an opening 194 that exposes an entirety or portion of the surface of the lower bump land 176L may be formed. A plurality of solder balls 196 may be formed at the bottom of the lower substrate 170.

Referring to FIG. 11E, the lower substrate 170 with the lower semiconductor chips 184 and lower molding material 192L formed therein is separated for each of the lower package areas LPAn and LPAn+1. A plurality of lower semiconductor packages 110L may be formed by the separating process. Through the separating process, the ground wire 178W and the ground line 182b that are formed over the adjacent lower package areas LPAn and LPAn+1 may be cut, and thus, the cut surface of the ground wire 178W may be exposed to a side surface of the lower molding material 192L, and the cut surface of the ground line 182b may be exposed to a side surface of the lower substrate 170.

Referring to FIG. 11F, a process in which the upper semiconductor package 110U that has been described above with reference to FIGS. 7A to 7D is stacked on the lower semiconductor package 110L is performed. The package bump 160 (connection bump) of the upper semiconductor package 110U undergoes a process in which the package bump 160 is dipped in a solder flux, and contacts the lower bump land 176L of the lower semiconductor package 110L through the opening 194 of the lower semiconductor package 110L.

Referring to FIG. 11G, the upper semiconductor package 110U and the lower semiconductor package 110L may be stacked. In this process, the package bump 160′ may be formed from the package bump 160 being heated and reflowed in the opening 194 of the lower semiconductor package 110L, and coupled and connected to the lower bump land 176L physically and electrically.

Referring to FIG. 11H, a process in which the cover 200 covers the stacked upper and lower semiconductor packages 110U and 110L and an attachment therebetween is performed may be performed. The cover 200 may include an adhesive 210 that is formed at an inner surface of the cover 200 contacting the upper molding material 192U. The cover 200 may contact one end portion 178W-b of the ground wire 178W that is exposed to a side surface 110Lb of the lower molding material 192L, and the ground line 182b that is exposed to a side surface of the lower substrate 170.

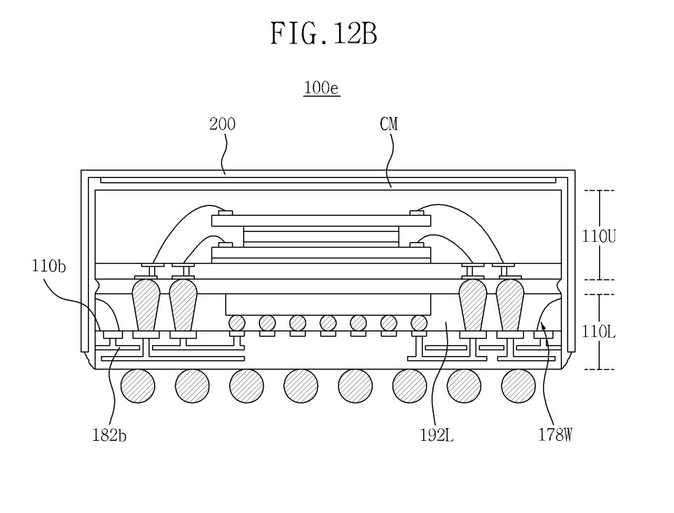

FIGS. 12A and 12B are longitudinal sectional views for describing a method of manufacturing a semiconductor device in accordance with an embodiment of the inventive concept. A method of manufacturing upper and lower semiconductor packages is the same as in the descriptions of FIGS. 11A to 11G, and thus, description thereof is not provided.

Referring to FIG. 12A, a conductive material CM may be provided on a top of stacked upper and lower semiconductor packages 110U and 110L by a defined amount. The conductive material CM may have flux, and may be a resin including a plurality of conductive metal balls. A process in which a cover 200 covers the stacked upper and lower semiconductor packages 110U and 110L may be performed.

Referring to FIG. 12B, a process in which the cover 200 covers the upper and lower semiconductor packages 110U and 110L and an attachment therebetween is performed may be performed. When a process of covering the stacked upper and lower semiconductor packages 110U and 110L by applying a certain pressure to the cover 200 is performed, the conductive material CM may be spread to a side surface and an entire top of each of the stacked upper and lower semiconductor packages 110U and 110L. Therefore, the conductive material CM may be disposed between the stacked upper and lower semiconductor packages 110U and 110L and the cover 200. The conductive material CM may simultaneously contact the cover 200, the ground wire 178W that is exposed to the side surface of the lower molding material 192L, and the ground line 182b that is exposed to the side surface of the lower substrate 170.

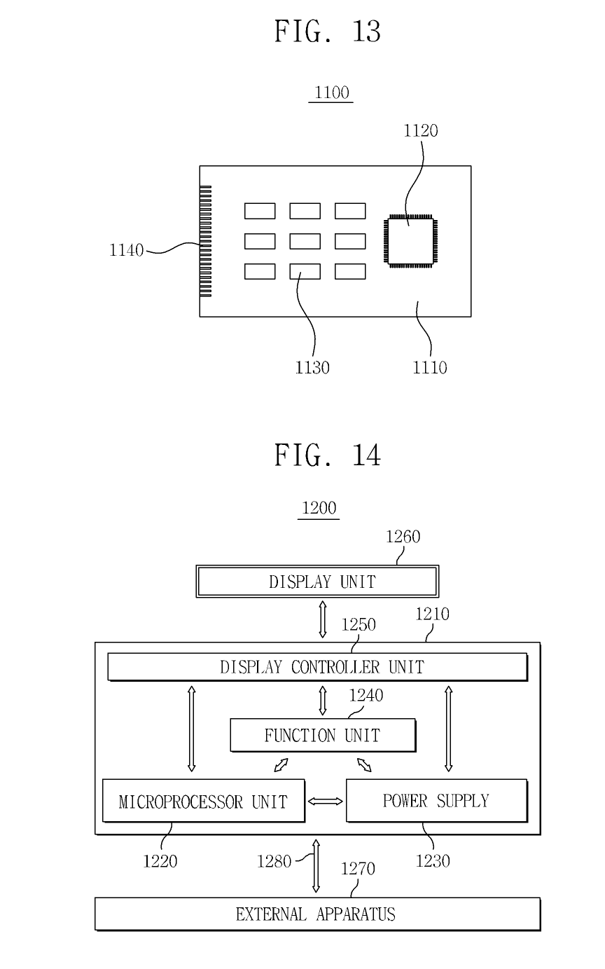

FIG. 13 is a view conceptually illustrating a module 1100 including a semiconductor device in accordance with embodiments of the inventive concept.

Referring to FIG. 13, the module 1100 in accordance with an embodiment of the inventive concept may include at least one of the semiconductor devices 100a to 100e as a semiconductor device 1130 in accordance with various embodiments of the inventive concept that is mounted on a module substrate 1110. The module 1100 may further include a microprocessor 1120 that is mounted on the module substrate 1110. A plurality of input/output terminals 1140 may be disposed in at least one side of the module substrate 1110 to electrically connect the microprocessor 1120 and/or the semiconductor device 1130 to an external device.

FIG. 14 is a block diagram conceptually illustrating an electronic system 1200 including at least one of the semiconductor devices 100a to 100e in accordance with various embodiments of the inventive concept.

Referring to FIG. 14, at least one of the semiconductor devices 100a to 100e in accordance with various embodiments of the inventive concept may be applied to the electronic system 1200. The electronic system 1200 may include a body 1210, a microprocessor unit 1220, a power supply 1230, a function unit 1240, and/or a display controller unit 1250. The body 1210 may be a motherboard or a system board that has a PCB and the like. The microprocessor unit 1220, the power supply 1230, the function unit 1240, and/or the display controller unit 1250 may be mounted or disposed on the body 1210. A display unit 1260 may be disposed on a top of the body 1210 or outside the body 1210. For example, the display unit 1260 may be disposed on a surface of the body 1210, and display an image that is processed by the display controller unit 1250. The power supply 1230 may receive a certain voltage from an external power source, divide the received voltage into various levels of voltages, and respectively supply the divided voltages to the microprocessor unit 1220, the function unit 1240, and the display controller unit 1250. The microprocessor unit 1220 may receive a voltage from the power supply 1230 to control the function unit 1240 and the display unit 1260. The function unit 1240 may perform various functions of the electronic system 1200. For example, when the electronic system 1200 is a mobile electronic device such as a mobile phone, the function unit 1240 may perform a wireless communication function such as the output of an image to the display unit 1260 and the output of sound to a speaker, according to dialing or in communication with an external apparatus 1270. When the electronic system 1200 includes a camera, the function unit 1240 may act as an image processor. In an application embodiment, when the electronic system 1200 is connected to a memory card for expanding a capacity, the function unit 1240 may be a memory card controller. The function unit 1240 may exchange a signal with the external apparatus 1270 through a wired or wireless communication unit 1280. Also, when the electronic system 1200 needs a universal serial bus (USB) and the like for expanding a function, the function unit 1240 may act as an interface controller. The display unit 1260 and the body 1210 may be formed as a single body. The display unit 1260 may be formed on a surface of the body 1210.

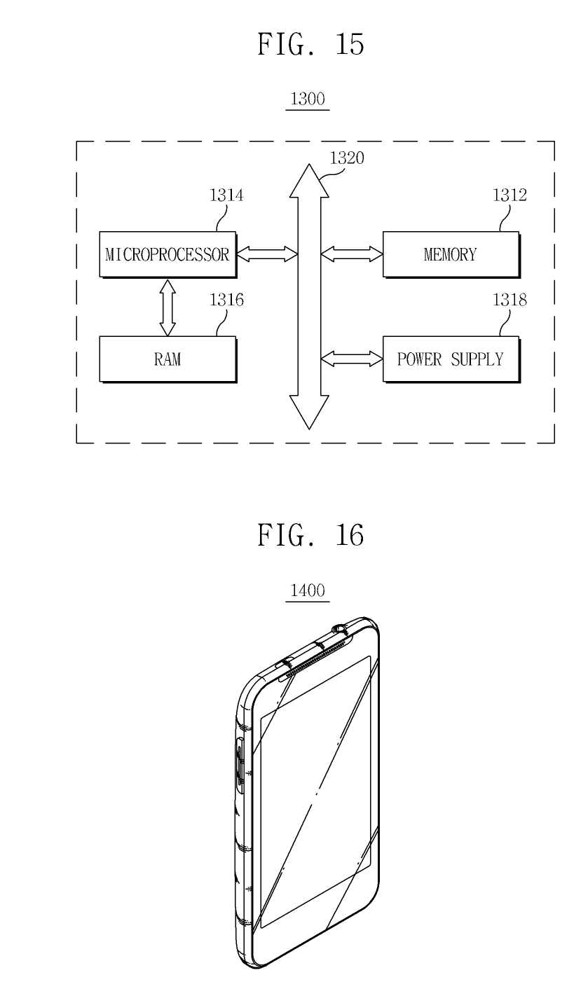

FIG. 15 is a block diagram conceptually illustrating an electronic system 1300 including at least one of the semiconductor devices 100a to 100e in accordance with various embodiments of the inventive concept.

Referring to FIG. 15, the electronic system 1300 may include at least one of the semiconductor devices 100a to 100e in accordance with various embodiments of the inventive concept. The electronic system 1300 may be applied to a mobile electronic device or a computer. For example, the electronic system 1300 may include a memory system 1312, a microprocessor 1314, a RAM 1316, and a power supply 1318 such that data communication can be performed using a bus 1320. The microprocessor 1314 may control a program and control the electronic system 1300. The RAM 1316 may be used as a working memory of the microprocessor 1314. For example, the microprocessor 1314 or the RAM 1316 may include at least one of the semiconductor devices 100a to 100e of FIGS. 1A-through 12B in accordance with various embodiments of the inventive concept. The microprocessor 1314, the RAM 1316, and/or the other elements may be assembled in a single package. The electronic system 1300 may include a user interface may be used to input/output data to/from the electronic system 1300. The user interface may be included in the microprocessor 1314. The user interface may communicate with an external device to perform data communication. The memory system 1312 may store a plurality of codes for operation of the microprocessor 1314, data processed by the microprocessor 1314, and/or external input data. The memory system 1312 may include a controller and a memory. The electronic system 1300 may include an input/output unit to input a user command or data and to output data corresponding to the user command or data.

FIG. 16 is a view schematically illustrating a mobile electronic device 2400 including at least one of the semiconductor devices 100a to 100e in accordance with various embodiments of the inventive concept.

The mobile electronic device 1400 may be understood as a tablet personal computer (PC). Additionally, at least one of the semiconductor devices 100a to 100e in accordance with various embodiments of the inventive concept may be applied to portable computers such as notebook computers, MPEG-1 audio layer 3 (MP3) players, MP4 players, navigation devices, solid state disks (SSDs), table computers, vehicles, and home appliances, in addition to tablet PCs.

As described above, the semiconductor device in accordance with the inventive concept has a structure in which the EMI shield covers the stacked semiconductor packages, thus shielding EMI that occurs in the semiconductor device.

Moreover, the EMI shield is electrically connected to the ground unit included in the semiconductor package having a stacked structure and thereby grounded to the outside, thus improving the EMI shielding effect.

According to the embodiments of the inventive concept, EMI can be effectively shielded, and thus, the operating characteristic of the semiconductor device can be stabilized.

Furthermore, the cover is formed of a metal material, and thus heat that is generated inside the semiconductor device is radiated to the outside through the cover.

The foregoing is illustrative of embodiments and is not to be construed as limiting thereof. Although a few embodiments have been described, those skilled in the art will readily appreciate that many modifications are possible in embodiments without materially departing from the novel teachings and advantages. Accordingly, all such modifications are intended to be included within the scope of this inventive concept as defined in the claims. In the claims, means-plus-function clauses are intended to cover the structures described herein as performing the recited function, and not only structural equivalents but also equivalent structures. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A method of manufacturing a semiconductor device, the method comprising:
forming a lower semiconductor package having a lower substrate, one or more semiconductor chips mounted on the lower substrate, and a ground unit connected to the lower substrate;
forming an upper semiconductor package having an upper substrate and one or more semiconductor chips mounted on the upper substrate and mounted on the lower semiconductor package; and
covering the lower semiconductor package and the upper semiconductor package with a cover and electrically connecting the cover to the ground unit to provide an EMI shield.

2. The method of claim 1, wherein the method comprises:
forming a wire as the ground unit to be connected between the cover and the lower substrate of the lower semiconductor package; and
connecting the wire to the cover during the covering operation as the EMI shield.

3. The method of claim 1, wherein the method comprises:
forming a ground line as the ground unit to be exposed through a side surface of the lower substrate; and
connecting the ground line to the cover during the covering operation as the EMI shield.

4. The method of claim 1, wherein the method comprises:
forming a conductive material to be disposed between the cover and at least one of the lower semiconductor package and the upper semiconductor package; and
connecting the ground unit to the conductive material as the EMI shield.
